(19) United States
(12) Patent Application Publication
(10) Pub. No.: US 2025/0366281 A1
(43) Pub. Date: Nov. 27, 2025

(54) MLED DEVICE HAVING A NANO SPONGE ELECTRODE PAD FOR HIGH-PRECISION BONDING AND MANUFACTURING METHOD OF THE SAME

(71) Applicant: Wavelord Co., Ltd., Gyeonggi-do (KR)

(72) Inventors: June O SONG, Gyeonggi-do (KR); Jihyung Moon, Gyeonggi-do (KR); Hyung Sun Yun, Gyeonggi-do (KR); Wyil Yun, Gyeonggi-do (KR)

(21) Appl. No.: 19/219,085

(22) Filed: May 27, 2025

(30) Foreign Application Priority Data
May 24, 2024 (KR) 10-2024-0068099
Feb. 20, 2025 (KR) 10-2025-0021884

(51) Int. Cl. H10H 20/857; H10H 20/01; H10H 20/831; H10H 20/832

(52) U.S. Cl. CPC H10H 20/857; H10H 20/018; H10H 20/032; H10H 20/0364; H10H 20/8312; H10H 20/832

(57) ABSTRACT

Embodiments according to the present invention provide an mLED device having a nano sponge electrode pad for high-precision bonding, comprising: a device structure including an n-type semiconductor layer having n-type conductivity; a p-type semiconductor layer having p-type conductivity; and an active layer generating photons by recombination of electrons and holes; and a nano sponge electrode pad (NSEP) electrically connected to one of the n-type semiconductor layer and the p-type semiconductor layer, wherein the nano sponge electrode pad is made of an electrically conductive metal having a nano sponge structure or a porous structure defined by nano-scale grooves or cavities.

### CROSS-REFERENCE TO RELATED APPLICATIONS

This application claims priority to Korean Patent Application Nos. 10-2024-0068099, filed on May 24, 2024 and 10-2025-0021884, filed on Feb. 20, 2025. The entire disclosure of the applications identified in this paragraph is incorporated herein by reference.

### FIELD

The present invention relates to an mLED device and a manufacturing method thereof, and more particularly, to an mLED device having a nano sponge electrode pad for high-precision bonding, in which an improved nano sponge structure is introduced into the electrode pad so as to be applicable to an mLED chip manufacturing process, and a manufacturing method thereof.

### BACKGROUND

Light-emitting diodes (LEDs) are inorganic light sources that have the advantages of long life, low power consumption, and fast response speed, and are widely used in various fields such as display devices, vehicle lamps, and general lighting.

The scope of application has expanded beyond the conventional use as a backlight light source to LED display devices that directly implement images using small-sized light-emitting diodes, namely micro LEDs (also called ‘mLEDs’, including ‘mini LEDs’).

Recently, technology development is being carried out for application to small display devices such as VR devices and mobile devices that require high resolution, but there are technical difficulties in manufacturing.

That is, as the LED chip size becomes smaller, the electrode pad of the LED chip must also be reduced, but there is a difficulty in maintaining electrical conductivity.

In addition, the technical difficulty of the process of transferring and bonding LED chips with reduced electrode pads to a specific substrate (interposer, PCB, TFT glass, or other panel) is increasing.

That is, in the case of LED chips (flip chips, horizontal chips) where two electrodes are located on the same surface, there is a problem of short-circuit defects (non-lighting) occurring due to spreading of the bonding material (solder, metal, etc.) between the two electrodes.

In the case of LED chips (vertical chips) where the two electrodes face in opposite directions, there is a problem of short-circuiting (non-lighting) due to spreading of the bonding material (solder, metal, etc.) between adjacent chips.

In addition, in the case of mLED chips, since the chip thickness is relatively thin, there is a problem that the bonding material diffuses to the side or top of the chip, which adversely affects the light output and quality.

Usually, the transfer & bonding process is performed as a reflow process, but there is a problem that the discharge amount control margin of the bonding material is very small, causing various types of quality issues.

### SUMMARY

### Technical Problem

The present invention provides an mLED device having a nano sponge electrode pad for high-precision bonding and a method for manufacturing the same that maintains electrical conductivity even when the electrode pad is reduced due to a decrease in chip size, and can improve issues occurring during the bonding process.

### Technical Solution

Embodiments according to the present invention provide an mLED device having a nano sponge electrode pad for high-precision bonding, comprising: a device structure including an n-type semiconductor layer having n-type conductivity; a p-type semiconductor layer having p-type conductivity; and an active layer generating photons by recombination of electrons and holes; and a nano sponge electrode pad (NSEP) electrically connected to one of the n-type semiconductor layer and the p-type semiconductor layer, wherein the nano sponge electrode pad is made of an electrically conductive metal having a nano sponge structure or a porous structure defined by nano-scale grooves or cavities.

The mLED device with nano-sponge electrode pad (NSEP) prevents solder spreading by absorbing the solder inside the nano-sponge during the bonding or transfer process. Specifically, the solder (mainly low-melting-point solder such as Zn, In, and Sn) is absorbed into the nano-sponge structure or porous structure by capillary phenomenon during the bonding process.

In embodiments according to the present invention, the nano sponge electrode pad is formed of an electrically conductive metal selected from gold (Au), silver (Ag), copper (Cu), platinum (Pt), palladium (Pd), and nickel (Ni), and the nano sponge structure or porous structure can be formed by deposition of an alloy using the electrically conductive metal as a solvent metal (Base metal or Matrix metal), and wet etching that removes a solute metal (Alloying element; e.g., low melting point solder) corresponding to the solvent metal from the alloy.

In addition, heat treatment may be performed prior to wet etching. This is to ensure that the solute metal exists in the form of three-dimensional particles or discontinuous regions within the solvent metal. Examples of alloys include Au—Sn, Au—In, Ag—In, Pd—In, Pt—In, Ni—Sn, and Cu—Sn.

Meanwhile, after forming a nano-sponge structure or a porous structure, a low-melting-point solder film is deposited on the nano-sponge structure. The low-melting-point solder film melts during the low-temperature bonding process to perform bonding, and some of it is absorbed into the nano-sponge structure. The low-melting-point solder film can be made of at least one of Zn, In, and Sn.

In embodiments according to the present invention, the nano sponge electrode pad may be provided by being bonded to either one of the n-type semiconductor layer and the p-type semiconductor layer, or may be provided as a separate layer and electrically connected to either one of the n-type semiconductor layer and the p-type semiconductor layer.

Embodiments according to the present invention are a method for manufacturing the mLED device, in which the nano sponge electrode pad can be applied to a flip chip structure.

Specifically, the method may comprise: a step of growing the n-type semiconductor layer, the active layer, and the p-type semiconductor layer by stacking them as the device structure on a growth substrate; a step of mesa etching so that a part of the n-type semiconductor layer is exposed; a step of forming a p-type ohmic contact electrode on the p-type semiconductor layer; an isolation step of etching the device structure so that it is divided into device units to form a unit device; a step of forming a passivation layer for mechanical, chemical protection, and electrical insulation of the device on an outer surface of the unit device; a step of etching the passivation layer so that a part of the p-type ohmic contact electrode and the n-type semiconductor layer are exposed; a step of depositing an alloy comprising an electrically conductive metal selected from gold (Au), silver (Ag), copper (Cu), platinum (Pt), palladium (Pd), and nickel (Ni) as a solvent metal, and at least one of Zn, In, and Sn as a solute metal corresponding to the solvent metal, on the exposed p-type ohmic contact electrode and the n-type semiconductor layer; a step of removing the solute metal from the alloy by wet etching to form the nano sponge electrode pad having the nano sponge structure or porous structure; and a step of bonding the unit device to a flip chip substrate on which a predetermined wiring is formed by turning the unit device over so that the growth substrate faces upward. Here, the nano sponge electrode pad may be additionally formed on the wiring of the flip chip substrate.

In contrast, a conventional electrode pad is formed on a part of the p-type ohmic contact electrode and the n-type semiconductor layer exposed by etching the passivation layer, and a nano-sponge electrode pad having a nano-sponge structure or a porous structure can be applied to the wiring of the flip-chip substrate.

Embodiments according to the present invention are a method for manufacturing the mLED device, in which a nano sponge electrode pad can be applied to a horizontal chip structure.

Specifically, the method may comprise: a step of growing the n-type semiconductor layer, the active layer, and the p-type semiconductor layer by stacking them as the device structure on a growth substrate; a step of mesa etching so that a part of the n-type semiconductor layer is exposed; a step of forming a p-type ohmic contact electrode on the p-type semiconductor layer; an isolation step of etching the device structure so that it is divided into device units to form a unit device; a step of forming a passivation layer for mechanical, chemical protection, and electrical insulation of the device on the outer surface of the unit device; a step of etching the passivation layer so that a part of the p-type ohmic contact electrode and the n-type semiconductor layer are exposed; a step of forming a p-side electrode pad and an n-side electrode pad on the exposed p-type ohmic contact electrode and the n-type semiconductor layer, respectively; a step of forming a resin adhesive coating layer that protects the passivation layer, electrically insulates and mechanically protects from an external environment, and flattens the upper surface of the unit device; a step of wafer bonding a first support substrate on the resin adhesive coating layer; a step of separating the growth substrate by an LLO (Laser Lift-Off) process and thinning the unit device; a step of flipping the unit device so that the first support substrate faces downward and depositing a DBR (Distributed Bragg Reflector) layer (or insulating film) on the thinned surface; a step of depositing an alloy comprising an electrically conductive metal selected from gold (Au), silver (Ag), copper (Cu), platinum (Pt), palladium (Pd), and nickel (Ni) as a solvent metal, and at least one of Zn, In, and Sn as a solute metal corresponding to the solvent metal, on the exposed p-type ohmic contact electrode and the n-type semiconductor layer; a step of removing the solute metal from the alloy by wet etching to form the nano sponge electrode pad having the nano sponge structure or porous structure; a step of wafer bonding a second support substrate on the nano sponge electrode pad; and a step of flipping the unit device so that the second support substrate faces downward, separating the first support substrate, and removing the resin adhesive coating layer.

Here, examples of the resin adhesive coating layer include SOG (spin on glass) and BCB (Benzocyclobutene) polymer.

Embodiments according to the present invention are a method for manufacturing the mLED device, in which the nano sponge electrode pad can be applied to a p-up growth and an n-up device structure as a vertical chip structure.

Specifically, the step of growing the n-type semiconductor layer, the active layer, and the p-type semiconductor layer as the device structure on a growth substrate by stacking them; the step of forming a p-type ohmic contact electrode formed as a reflective electrode on the p-type semiconductor layer; the step of depositing an alloy on the p-type ohmic contact electrode, the electrically conductive metal selected from gold (Au), silver (Ag), copper (Cu), platinum (Pt), palladium (Pd), and nickel (Ni) as a solvent metal, and the alloy containing at least one of Zn, In, and Sn as a solute metal corresponding to the solvent metal; the step of removing the solute metal from the alloy by wet etching to form the nano sponge electrode pad having the nano sponge structure or porous structure; It may include a step of wafer bonding a support substrate on the nano sponge electrode pad; a step of separating the growth substrate by an LLO (Laser Lift-Off) process and thinning it; and a step of flipping the unit device so that the support substrate faces downward and forming an n-type ohmic contact electrode on the thinned n-type semiconductor layer.

Embodiments according to the present invention are a method for manufacturing the mLED device, in which the nano sponge electrode pad can be applied to p-up growth and p-up device structures as vertical chip structure.

Specifically, the step of growing the n-type semiconductor layer, the active layer, and the p-type semiconductor layer by stacking them as the device structure on a growth substrate; the step of forming a p-type ohmic contact electrode on the p-type semiconductor layer; the step of wafer bonding a third support substrate on the p-type ohmic contact electrode; the step of separating the growth substrate by an LLO (Laser Lift-Off) process and thinning it; and the step of flipping the unit device so that the third support substrate faces downward and forming an n-type ohmic contact electrode on the thinned n-type semiconductor layer; The method may include: depositing an alloy comprising an electrically conductive metal selected from gold (Au), silver (Ag), copper (Cu), platinum (Pt), palladium (Pd), and nickel (Ni) as a solvent metal, and a solute metal corresponding to the solvent metal, and including at least one of Zn, In, and Sn, on the n-type ohmic contact electrode; removing the solute metal from the alloy by wet etching to form the nano sponge electrode pad having the nano sponge structure or porous structure; wafer bonding a fourth support substrate on the nano sponge electrode pad; and flipping the unit device so that the fourth support substrate faces downward, separating the third support substrate, and exposing the p-type ohmic contact electrode.

### Advantageous Effects

According to the present invention, since solder is absorbed by the nano sponge structure or porous structure of the nano sponge electrode pad (NSEP) during the bonding or transfer process, it has the advantage of dramatically improving issues occurring during the bonding or transfer process.

According to the present invention, despite the reduction in electrode pad size due to miniaturization of chip size, excellent electrical conductivity can be maintained by a nano sponge electrode pad (NSEP).

According to the present invention, the nano sponge electrode pad can be formed in various mLED chip structures.

### BRIEF DESCRIPTION OF DRAWINGS

FIGS. 1, 2, 3 and 4 are drawings showing one embodiment of an mLED device having a nano sponge electrode pad for high-precision bonding according to the present invention.

FIG. 5 is a drawing for explaining one embodiment of a method for manufacturing an mLED devices having a nano sponge electrode pad for high-precision bonding according to the present invention.

FIG. 6 is a drawing showing an example of bonding the mLED device according to FIG. 5 to a flip chip substrate.

FIGS. 7, 8 and 9 are drawings for explaining another embodiments of a method for manufacturing an mLED device having a nano sponge electrode pad for high-precision bonding according to the present invention.

### DETAILED DESCRIPTION

Hereinafter, an mLED device having a nano sponge electrode pad for high-precision bonding and manufacturing method of the same according to embodiments of the present invention will be described in detail with reference to the drawings.

The terms used below have been selected for convenience of explanation, and should be appropriately interpreted in a meaning that is consistent with the technical idea of the present invention without being limited to the dictionary meaning.

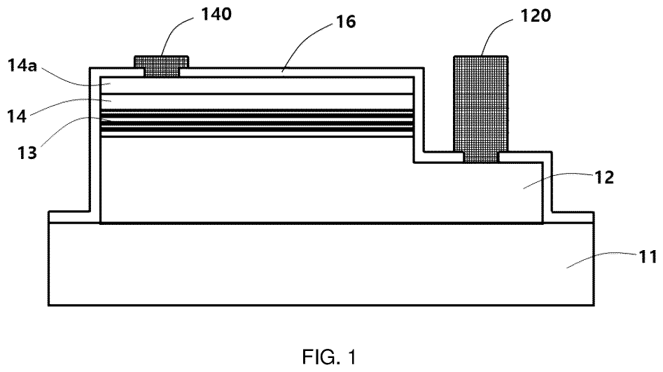

Referring to FIG. 1, an mLED device having a nano sponge electrode pad for high-precision bonding according to the present embodiment includes a device structure and nano sponge electrode pads (NSEP, 120, 140).

The device structure is configured to include an n-type semiconductor layer (12) having n-type conductivity, a p-type semiconductor layer (14) having p-type conductivity, and an active layer (13) that generates photons by recombination of electrons and holes.

The device structure is not limited to the materials (or compounds) that constitute the n-type semiconductor layer (12), the p-type semiconductor layer (14), and the active layer (13) as long as inorganic light emission is achieved.

In addition, the material of the growth substrate on which the device structure is epitaxially grown is not limited.

Nano sponge electrode pads (NSEPs; 120, 140) are electrically connected to the n-type semiconductor layer (12) or the p-type semiconductor layer (14).

The meaning of electrical connection includes not only being directly connected to the n-type semiconductor layer (12) or the p-type semiconductor layer (14), but also being connected indirectly to the n-type semiconductor layer (12) or the p-type semiconductor layer (14) via a material or material layer that is electrically conductive and is provided as a separate layer.

Nano sponge electrode pads (120, 140) are made of electrically conductive metal having a nano sponge structure or porous structure defined by nanoscale grooves or cavities.

During the bonding or transfer process of the mLED device having the nano sponge electrode pad (NSEP), some of low melting point solders such as Zn, In, and Sn are absorbed into the nano sponge pad. Specifically, the low-melting-point solder is absorbed into the nano-sponge structure or porous structure by capillary phenomenon during the bonding or transfer process.

Thereby, the spreading of the solder during the bonding or transfer process is prevented.

Here, the nano-sponge electrode pad is formed of one electrically conductive metal selected from gold (Au), silver (Ag), copper (Cu), platinum (Pt), palladium (Pd), and nickel (Ni), and the nano-sponge structure or porous structure can be formed by deposition of an alloy using the electrically conductive metal as a solvent metal and wet etching to remove the solute metal (e.g., low-melting-point solder) corresponding to the solvent metal from the alloy.

In addition, heat treatment can be performed before the wet etching. This is to ensure that the solute metal exists in the form of three-dimensional particles or discontinuous regions inside the solvent metal.

The alloy may be, for example, Au—Sn, Au—In, Ag—In, Pd—In, Pt—In, Ni—Sn, and Cu—Sn.

Meanwhile, after forming the nano sponge structure or the porous structure, a low-melting-point solder film of Zn, In, and Sn may be deposited on the nano sponge structure. The low-melting-point solder film performs bonding in a low-temperature bonding process.

The alloy deposition may be performed by electroplating, PVD (e-beam, sputtering).

FIG. 1 shows an example in which a nano sponge electrode pad is applied to a flip chip structure, in which the nano sponge electrode pad (120, 140) is directly bonded to an n-type semiconductor layer (12) or a p-type semiconductor layer (14).

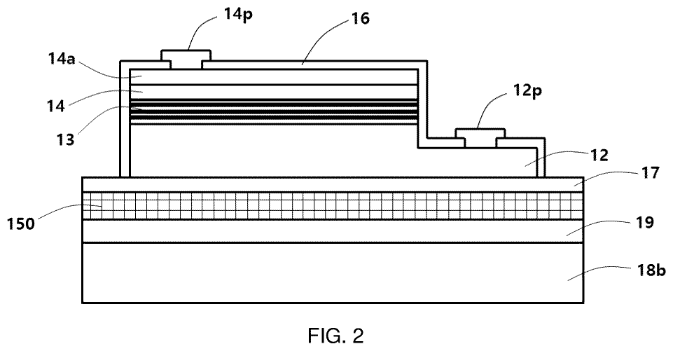

FIG. 2 shows an example in which a nano sponge electrode pad is applied to a horizontal chip structure, and the nano sponge electrode pad (150) is provided as a separate layer, and is provided adjacent to an n-type semiconductor layer (12) with a DBR (Distributed Bragg Reflector) layer (or insulating film) (17) as an insertion layer.

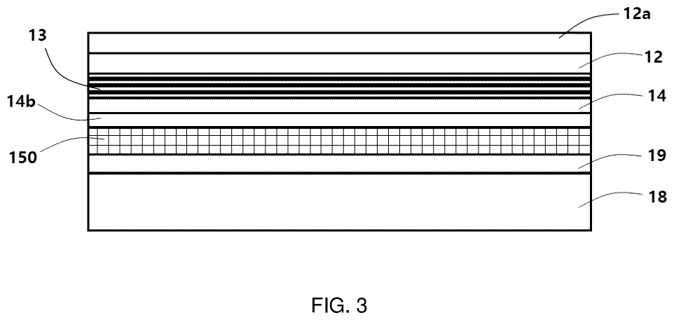

FIG. 3 shows an example of a vertical chip structure in which a nano sponge electrode pad is applied. The vertical chip structure is a structure in which the n-type semiconductor layer (12) is located on the upper side, but the p-type semiconductor layer (14) is epitaxially grown to be located on the upper side.

Referring to FIG. 3, the nano sponge electrode pad (150) is provided by being joined to a p-type ohmic contact electrode (14b) formed as a reflective electrode on one surface of the p-type semiconductor layer (14).

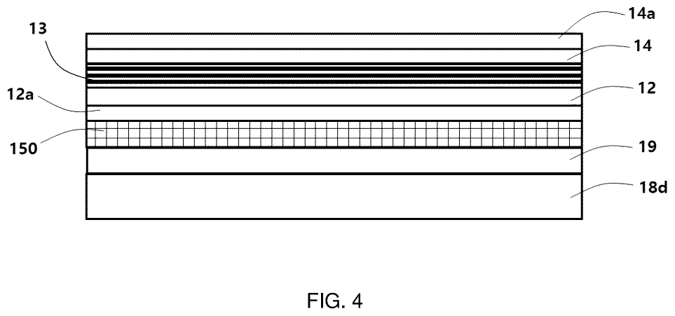

FIG. 4 shows an example of a vertical chip structure in which a nano sponge electrode pad is applied. The vertical chip structure is a structure in which the p-type semiconductor layer (12) is located on the upper side, and the p-type semiconductor layer (14) is epitaxially grown to be located on the upper side.

Referring to FIG. 4, a nano sponge electrode pad (150) is provided by being joined to an n-type ohmic contact electrode (12a) formed on one surface of an n-type semiconductor layer (12).

Next, embodiments of the manufacturing method of the mLED device according to the present invention are described.

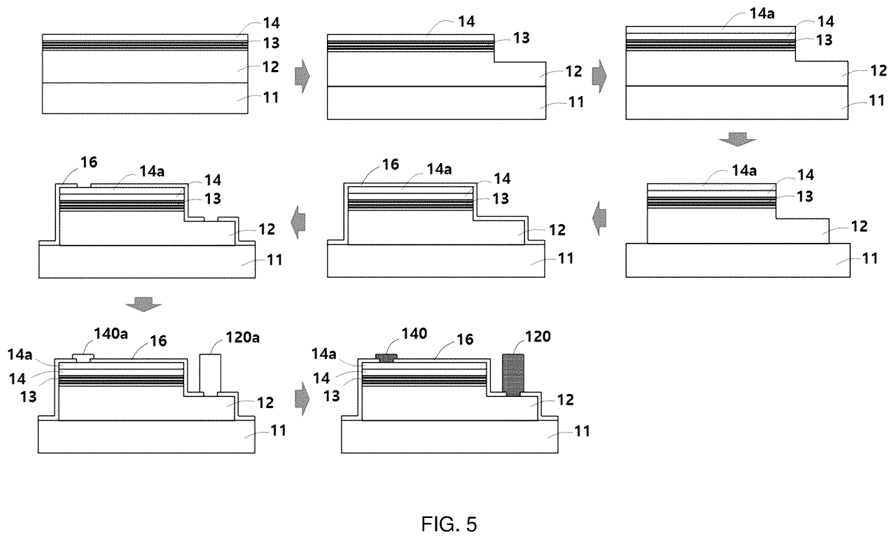

FIG. 5 shows an example of the manufacturing method of the mLED device according to the present invention, in which a nano sponge electrode pad is applied to a flip chip structure.

In this embodiment, first, an n-type semiconductor layer (12), an active layer (13), and a p-type semiconductor layer (14) are sequentially grown as a device structure on a growth substrate (11).

Afterwards, a mesa etching is performed so that a part of the n-type semiconductor layer (12) is exposed, and a p-type ohmic contact electrode (14a) is formed on the p-type semiconductor layer (14).

Next, an isolation step is performed in which the device structure is etched into device units to form unit devices.

Afterwards, a passivation layer (16) is formed on the outer surface of the unit device for mechanical, chemical protection, and electrical insulation of the device, and the passivation layer is etched so that a part of the p-type ohmic contact electrode (14a) and the n-type semiconductor layer (12) are exposed.

Next, an alloy (120a, 140a) composed of an electrically conductive metal selected from gold (Au), silver (Ag), copper (Cu), platinum (Pt), palladium (Pd), and nickel (Ni) as a solvent metal and a solute metal corresponding to the solvent metal is deposited on the exposed p-type ohmic contact electrode (14a) and the n-type semiconductor layer (12). Examples of the solute metal include Zn, In, and Sn.

Afterwards, by wet etching, the solute metal is removed from the alloy (120a, 140a) to form a nano sponge electrode pad (120, 140) having a nano sponge structure or a porous structure.

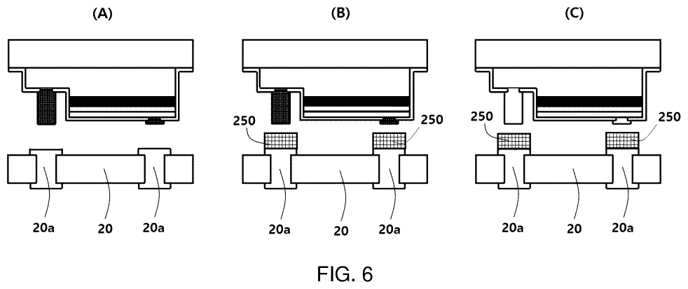

Referring to FIG. 6, a step may be included of bonding a unit device to a flip chip substrate (20) on which a predetermined wiring (20a) is formed by flipping the unit device so that the growth substrate (11) faces upward (see (A) of FIG. 6).

Here, a nano sponge electrode pad (250) may be additionally formed on the wiring (20a) of the flip chip substrate (20) (see (B) of FIG. 6).

Meanwhile, a conventional electrode pad is formed on a part of the p-type ohmic contact electrode (14a) and the n-type semiconductor layer (12) exposed by etching the passivation layer (16), and a nano sponge electrode pad (250) having a nano sponge structure or porous structure can be applied in a method of forming it on the wiring (20a) of the flip chip substrate (20) (see (C) of FIG. 6).

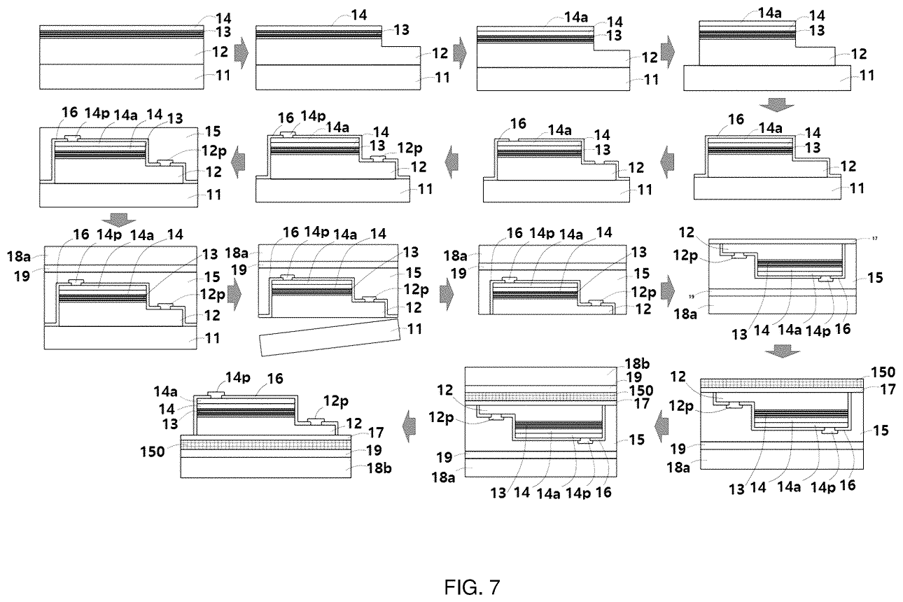

FIG. 7 shows an example of a method for manufacturing an mLED device according to the present invention, in which a nano sponge electrode pad is applied to a horizontal chip structure.

In this embodiment, an n-type semiconductor layer (12), an active layer (13), and a p-type semiconductor layer (14) are stacked and grown as a device structure on a growth substrate (11), a mesa etch is performed so that a part of the n-type semiconductor layer (12) is exposed, a p-type ohmic contact electrode (14a) is formed on the p-type semiconductor layer (14), and the device structure is etched so that it is divided into device units to form a unit device. After that, a passivation layer (16) is formed on the outer surface of the unit device for mechanical, chemical protection, and electrical insulation of the device, and the process of etching the passivation layer (16) so that a part of the p-type ohmic contact electrode (14a) and the n-type semiconductor layer (12) are exposed is the same as the previously described embodiment of FIG. 5.

However, in this embodiment, a step is performed to form a p-side electrode pad (14p) and an n-side electrode pad (12p) on the exposed p-type ohmic contact electrode (14a) and n-type semiconductor layer (12), respectively, to protect the passivation layer (16), to electrically insulate and mechanically protect from the external environment, and to form a resin adhesive coating layer (15) that flattens the upper surface of the unit device.

Here, the resin adhesive coating layer (15) can be, for example, a SOG (spin on glass) material.

Thereafter, a first support substrate (18a) is wafer bonded (19) on the resin adhesive coating layer (15), the growth substrate (11) is separated by an LLO (Laser Lift-Off) process, and a step of thinning the device is performed.

Afterwards, the unit device is turned over so that the first support substrate (18a) faces downward, and a DBR (Distributed Bragg Reflector) layer (or insulating film) (17) is deposited on the thinned surface.

Next, an alloy composed of an electrically conductive metal selected from gold (Au), silver (Ag), copper (Cu), platinum (Pt), palladium (Pd), and nickel (Ni) as a solvent metal and a solute metal (e.g., Zn, In, and Sn) corresponding to the solvent metal is deposited on the DBR layer (17), and the solute metal is removed from the alloy by wet etching to form a nano sponge electrode pad (150) having a nano sponge structure or a porous structure.

Afterwards, a second support substrate (18b) is wafer bonded (19) on top of a nano sponge electrode pad (150), the unit device is turned over so that the second support substrate (18b) faces downward, the first support substrate (18a) is separated, and the resin adhesive coating layer (15) is removed to complete the device.

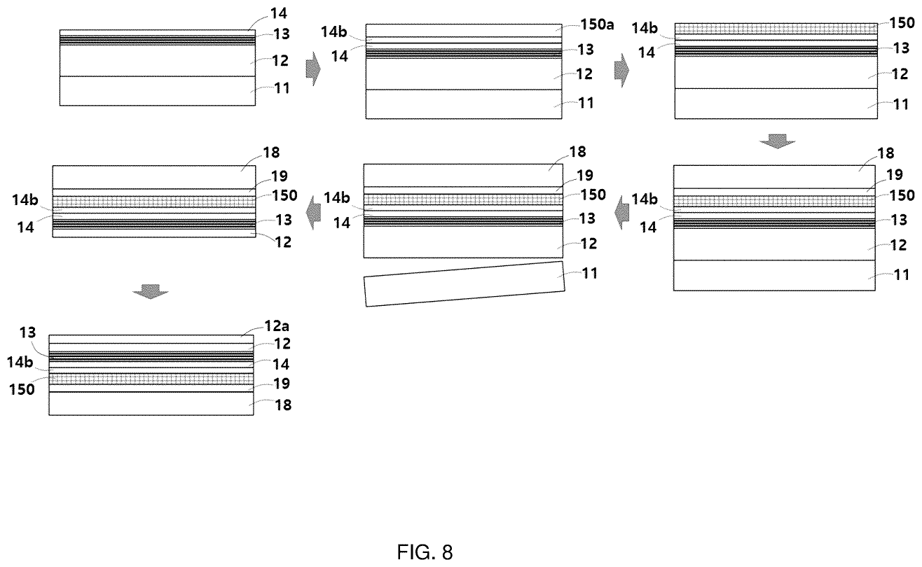

FIG. 8 shows an example of a method for manufacturing an mLED device according to the present invention, in which a nano sponge electrode pad is applied to a p-up growth and n-up device structure as a vertical chip structure.

In this embodiment, an n-type semiconductor layer (12), an active layer (13), and a p-type semiconductor layer (14) are sequentially grown as a device structure on a growth substrate (11), and a p-type ohmic contact electrode (14a) formed as a reflective electrode is formed on the p-type semiconductor layer (14).

Thereafter, a nano sponge electrode pad (150) is formed on the p-type ohmic contact electrode (14a).

As described above, in order to form a nano sponge electrode pad (150), first, an alloy (150a) is deposited, which is made of an electrically conductive metal selected from among gold (Au), silver (Ag), copper (Cu), platinum (Pt), palladium (Pd), and nickel (Ni) as a solvent metal, and a solute metal (e.g., Zn, In, and Sn) corresponding to the solvent metal.

Next, the solute metal is removed from the alloy (150a) by wet etching to form a nano sponge electrode pad (150) having a nano sponge structure or porous structure.

Thereafter, a support substrate (18) is wafer bonded (19) on the nano sponge electrode pad (150), the growth substrate (11) is separated by an LLO (Laser Lift-Off) process, and the device is thinned.

Next, the unit device is turned over so that the support substrate (18) faces downward, and an n-type ohmic contact electrode (12a) is formed on the thinned n-type semiconductor layer (12) to complete the device.

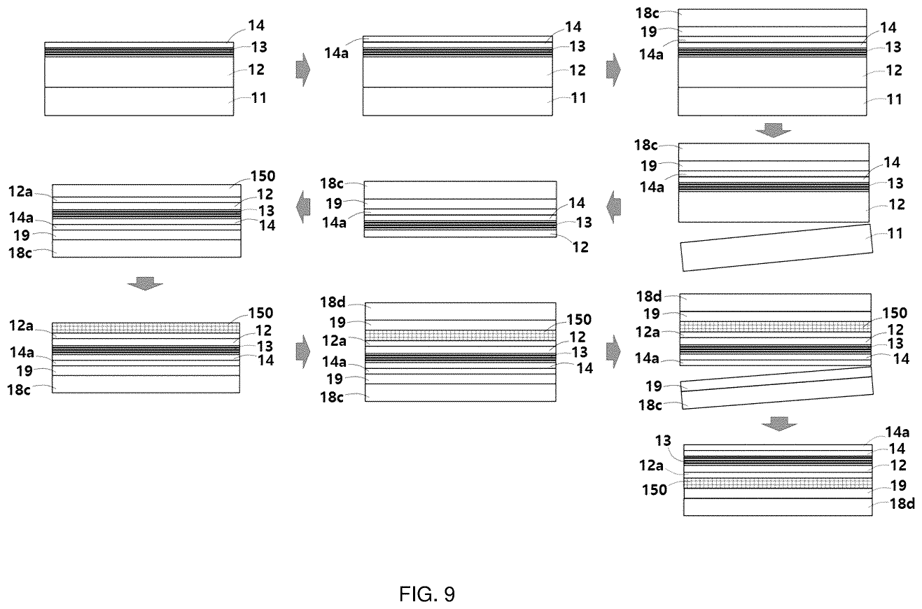

FIG. 9 shows an example of a method for manufacturing an mLED device according to the present invention, in which a nano sponge electrode pad is applied to a p-up growth and p-up device structure as a vertical chip structure.

In this embodiment, an n-type semiconductor layer (12), an active layer (13), and a p-type semiconductor layer (14) are sequentially grown as a device structure on a growth substrate (11), and a p-type ohmic contact electrode (14a) is formed on the p-type semiconductor layer (14).

Thereafter, a third support substrate (18c) is wafer bonded (19) on the p-type ohmic contact electrode (14a), the growth substrate (11) is separated by an LLO (Laser Lift-Off) process, and the device is thinned.

Next, the unit device is flipped over so that the third support substrate (18c) faces downward, and an n-type ohmic contact electrode (12a) is formed on the thinned n-type semiconductor layer (12).

Thereafter, a nano sponge electrode pad (150) is formed on the n-type ohmic contact electrode (12a).

First, an alloy (150a) composed of an electrically conductive metal selected from gold (Au), silver (Ag), copper (Cu), platinum (Pt), palladium (Pd), and nickel (Ni) as a solvent metal and a solute metal (e.g., Zn, In, and Sn) corresponding to the solvent metal is deposited.

Thereafter, the solute metal is removed from the alloy (150a) by wet etching to form a nano sponge electrode pad (150) having a nano sponge structure or a porous structure.

Next, the fourth support substrate (18d) is wafer bonded (19) on the nano sponge electrode pad (150), the unit device is turned over so that the fourth support substrate (18d) faces downward, the third support substrate (18c) is separated, and the p-type ohmic contact electrode is exposed to complete the device.

According to the embodiments of the present invention described above, the nano sponge electrode pad (NSEP) has a nano sponge structure or porous structure, so that the melted solder is absorbed and included in the nano sponge structure or porous structure during the bonding process, thereby having the advantage of dramatically improving the issues occurring during the bonding process.

In addition, the nano sponge electrode pad (NSEP) has the advantage of maintaining excellent electrical conductivity even when the electrode pad is reduced due to miniaturization of the chip size.

What is claimed is:

1. An mLED device having a nano sponge electrode pad for high-precision bonding, comprising:
a device structure having an n-type semiconductor layer with n-type conductivity; a p-type semiconductor layer with p-type conductivity; and an active layer generating photons by recombination of electrons and holes; and
a nano sponge electrode pad (NSEP) electrically connected to one of the n-type semiconductor layer and the p-type semiconductor layer,
wherein the nano sponge electrode pad is made of an electrically conductive metal having a nano sponge structure or a porous structure defined by nano-scale grooves or cavities.

2. The mLED device of claim 1, wherein the nano sponge electrode pad is formed of an electrically conductive metal selected from gold (Au), silver (Ag), copper (Cu), platinum (Pt), palladium (Pd), and nickel (Ni), and
the nano sponge structure or porous structure can be formed by deposition of an alloy using the electrically conductive metal as a solvent metal, and wet etching that removes a solute metal corresponding to the solvent metal from the alloy.

3. The mLED device of claim 1, wherein the nano sponge electrode pad is provided by being bonded to either one of the n-type semiconductor layer and the p-type semiconductor layer, or is provided as a separate layer and electrically connected to either one of the n-type semiconductor layer and the p-type semiconductor layer.

4. A method for manufacturing the mLED device of claim 1, comprising:
a step of sequentially growing the n-type semiconductor layer, the active layer, and the p-type semiconductor layer as the device structure on a growth substrate;
a step of mesa etching so that a part of the n-type semiconductor layer is exposed;
a step of forming a p-type ohmic contact electrode on the p-type semiconductor layer;
an isolation step of etching the device structure so that it is divided into device units to form a unit device;
a step of forming a passivation layer for mechanical, chemical protection, and electrical insulation of the device on an outer surface of the unit device;
a step of etching the passivation layer so that a part of the p-type ohmic contact electrode and the n-type semiconductor layer are exposed;
a step of depositing an alloy comprising an electrically conductive metal selected from gold (Au), silver (Ag), copper (Cu), platinum (Pt), palladium (Pd), and nickel (Ni) as a solvent metal, and at least one of Zn, In, and Sn as a solute metal corresponding to the solvent metal, on the exposed p-type ohmic contact electrode and the n-type semiconductor layer;
a step of removing the solute metal from the alloy by wet etching to form the nano sponge electrode pad having the nano sponge structure or porous structure; and
a step of bonding the unit device to a flip chip substrate on which a predetermined wiring is formed by turning the unit device over so that the growth substrate faces upward.

5. A method for manufacturing the mLED device of claim 1, comprising:
a step of growing the n-type semiconductor layer, the active layer, and the p-type semiconductor layer by stacking them as the device structure on a growth substrate;
a step of mesa etching so that a part of the n-type semiconductor layer is exposed;
a step of forming a p-type ohmic contact electrode on the p-type semiconductor layer;
an isolation step of etching the device structure so that it is divided into device units to form a unit device;
a step of forming a passivation layer for mechanical, chemical protection, and electrical insulation of the device on the outer surface of the unit device;
a step of etching the passivation layer so that a part of the p-type ohmic contact electrode and the n-type semiconductor layer are exposed;
a step of forming a p-side electrode pad and an n-side electrode pad on the exposed p-type ohmic contact electrode and the n-type semiconductor layer, respectively;
a step of forming a resin adhesive coating layer that protects the passivation layer, electrically insulates and mechanically protects from an external environment, and flattens the upper surface of the unit device;
a step of wafer bonding a first support substrate on the resin adhesive coating layer;
a step of separating the growth substrate by an LLO (Laser Lift-Off) process and thinning the unit device;
a step of flipping the unit device so that the first support substrate faces downward and depositing a DBR (Distributed Bragg Reflector) layer (or insulating film) on the thinned surface;
a step of depositing an alloy comprising an electrically conductive metal selected from gold (Au), silver (Ag), copper (Cu), platinum (Pt), palladium (Pd), and nickel (Ni) as a solvent metal, and at least one of Zn, In, and Sn as a solute metal corresponding to the solvent metal, on the exposed p-type ohmic contact electrode and the n-type semiconductor layer;
a step of removing the solute metal from the alloy by wet etching to form the nano sponge electrode pad having the nano sponge structure or porous structure;
a step of wafer bonding a second support substrate on the nano sponge electrode pad; and
a step of flipping the unit device so that the second support substrate faces downward, separating the first support substrate, and removing the resin adhesive coating layer.

6. A method for manufacturing the mLED device of claim 1, comprising:
a step of growing the n-type semiconductor layer, the active layer, and the p-type semiconductor layer as the device structure on a growth substrate by stacking them;
a step of forming a p-type ohmic contact electrode formed as a reflective electrode on the p-type semiconductor layer;
a step of depositing an alloy comprising an electrically conductive metal selected from gold (Au), silver (Ag), copper (Cu), platinum (Pt), palladium (Pd), and nickel (Ni) as a solvent metal, and at least one of Zn, In, and Sn as a solute metal corresponding to the solvent metal, on the p-type ohmic contact electrode;
a step of removing the solute metal from the alloy by wet etching to form the nano sponge electrode pad having the nano sponge structure or porous structure;
a step of wafer bonding a support substrate on the nano sponge electrode pad;
a step of separating the growth substrate by an LLO (Laser Lift-Off) process and thinning the n-type semiconductor layer; and
a step of flipping so that the support substrate faces downward and forming an n-type ohmic contact electrode on the thinned n-type semiconductor layer.

7. A method for manufacturing the mLED device of claim 1, comprising:
a step of growing the n-type semiconductor layer, the active layer, and the p-type semiconductor layer by stacking them as the device structure on a growth substrate;
a step of forming a p-type ohmic contact electrode on the p-type semiconductor layer;
the step of wafer bonding a third support substrate on the p-type ohmic contact electrode;
a step of separating the growth substrate by an LLO (Laser Lift-Off) process and thinning the n-type semiconductor layer;
a step of flipping so that the third support substrate faces downward and forming an n-type ohmic contact electrode on the thinned n-type semiconductor layer;
a step of depositing an alloy comprising an electrically conductive metal selected from gold (Au), silver (Ag), copper (Cu), platinum (Pt), palladium (Pd), and nickel (Ni) as a solvent metal, and a solute metal corresponding to the solvent metal, and including at least one of Zn, In, and Sn, on the n-type ohmic contact electrode;
a step of removing the solute metal from the alloy by wet etching to form the nano sponge electrode pad having the nano sponge structure or porous structure;
a step of wafer bonding a fourth support substrate on the nano sponge electrode pad; and
a step of flipping so that the fourth support substrate faces downward, separating the third support substrate, and exposing the p-type ohmic contact electrode.
